(19) United States
(12) Patent Application Publication
(10) Pub. No.: US 2026/0231552 A1
(43) Pub. Date: Aug. 6, 2026

(54) THROUGH-SILICON VIAS FOR INTEGRATED CIRCUIT INTERCONNECT

(71) Applicant: Taiwan Semiconductor Manufacturing Company, Ltd., Hsinchu (TW)

(72) Inventor: Ke-Jing YU, Kaohsiung City (TW)

(73) Assignee: Taiwan Semiconductor Manufacturing Company, Ltd., Hsinchu (TW)

(21) Appl. No.: 19/045,146

(22) Filed: Feb. 4, 2025

(51) Int. Cl. H10F 39/00

(52) U.S. Cl. CPC H10F 39/811; H10F 39/026; H10F 39/8037

(57) ABSTRACT

This disclosure is directed to a structure of a semiconductor device and a method of forming the structure. The structure can include a substrate having active regions and dummy regions on a first side of the substrate. The active regions can include active transistors for normal operation of the semiconductor device, whereas the dummy regions can include dummy structures (such as dummy transistors) to avoid the problem of dishing due to the loading effect during manufacturing the structure. The dummy structures can electrically couple to the active transistors via buried contacts in the substrate. The structure can further include a chip bonded to a second side of the substrate and TSVs in contact with the dummy structures and a bonding pad on the second side of the substrate. Each of the TSVs can be in contact with an array of the dummy structures.

### BACKGROUND

The semiconductor integrated circuit (IC) industry has experienced exponential growth. In three-dimensional (3D) IC packaging, through-silicon vias (TSVs) can be used to connect ICs/components on opposite sides of a silicon wafer substrate/die (or any suitable structure). A TSV is an electrical connection that passes/extends through the silicon wafer substrate/die and connects devices/structures (e.g., metal interconnects) on the opposite sides of the silicon wafer substrate/die.

### BRIEF DESCRIPTION OF THE DRAWINGS

Aspects of the present disclosure are best understood from the following detailed description when read with the accompanying figures. It is noted that, in accordance with the common practice in the industry, various features are not drawn to scale. In fact, the dimensions of the various features may be arbitrarily increased or reduced for clarity of illustration and discussion.

FIG. 1 a cross-sectional view of a stacked device with through-silicon vias, according to some embodiments.

FIGS. 2A, 2B, 2C, 2D, 2E, 2F, 2G, 2H, and 2I are cross-sectional views of structures including a through-silicon via and dummy MOS structures, in accordance with some embodiments.

FIGS. 3A, 3B, 3C, 3D, and 3E are plan views of structures including through-silicon vias and dummy MOS structures, according to some embodiments.

FIG. 4 is a flowchart of a method for the formation of a semiconductor device, in accordance with some embodiments.

FIGS. 5, 6, 7, 8, 9, and 10 are cross-sectional views of intermediate structures during the fabrication of a semiconductor device, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed that are between the first and second features, such that the first and second features are not in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “about” and “substantially” can refer to a percentage of the values as interpreted by those skilled in relevant art(s) in light of the teachings herein.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

A three-dimensional (3D) system on integrated chip (“3D SoIC”) structure is a non-monolithic vertical structure that includes multiple chips stacked vertically on top of each other. Different types of chips, performing different functions, can be stacked in the 3D SoIC structure. For example, the 3D SoIC device of a contact image sensor (CIS) can include a sensor chip, a pixel transistor chip, and an image processing chip. By way of example and not limitation, the sensor chip can include photo diode arrays that generate photo-excited charge carriers and can be stacked on a first side of the pixel transistor chip. The pixel transistor chip can transform the photo-excited charge carriers into electrical signals. The image processing chip can be stacked on a second side of the pixel transistor chip and can include image processing units to construct the digital images from the electrical signals. In the 3D SoIC structure, the chips in the stack can be electrically and mechanically coupled together through conductive structures, such as different types of bonding structures (e.g., homogeneous or hybrid) and through silicon via (TSV) structures. For example, a chip can include electrical components (e.g., transistors, resistors, capacitors, and inductors) on a first side of a substrate. The chip can also include interconnect structures on the first side to electrically couple the electrical components. A second side of the substrate can include a bonding pad and can be bonded with another chip. A TSV structure in the chip can be disposed through the entirety (or most) of the thickness of the substrate, with the interconnect structures and the bonding pad in contact with first and second ends of the TSV structure, respectively, to establish electrical connection between the electrical components of the chip and those on other chips.

As semiconductor devices continue to scale down, critical dimensions of the electrical components and the interconnect structures coupling them become increasingly smaller, reducing the resistive-capacitive (RC) delay and increasing the operation speed of the semiconductor devices. However, the scheme of coupling the TSV with the electrical components via the interconnect structures as described above can cause long current paths and can limit the operation speed between electrical components on different chips.

The embodiments described herein are directed to address the challenges mentioned above. In some embodiments, a structure of a semiconductor device can include a substrate having active regions and dummy regions on a first side of the substrate. The active regions can include active transistors for normal operations of the semiconductor device, whereas the dummy regions are areas on the substrate unoccupied by active transistors and with dummy structures (such as dummy transistors with partial or complete shapes of active transistors and not performing the normal operations) taking the space to avoid the problem of dishing due to the loading effect during the process of manufacturing the structure. The dummy structures can electrically couple to the active transistors via buried contacts in or on the substrate. The structure can also include a chip bonded to a second side of the substrate. The structure can further include TSVs through the substrate and in contact with the dummy structures and a bonding pad on the second side of the substrate. Each of the TSVs can be in contact with an array of the dummy structures. By taking advantage of the dummy structures, instead of the interconnect structures, to connect the TSVs and the active transistors, the current paths between the active transistors on the first side of the substrate and electrical components in the chip bonded to the second side of the substrate can be shortened, improving the performance of the semiconductor device by reducing the RC delay.

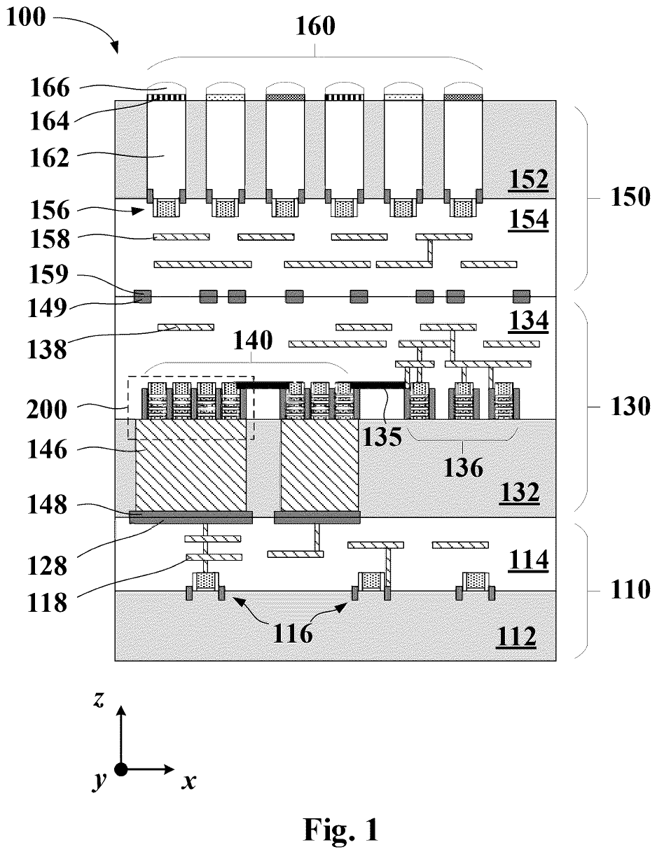

FIG. 1 is a cross-sectional view of a stacked device 100, according to some embodiments. By way of example and not limitation, stacked device 100 is a 3D SoIC structure. By way of example and not limitation, stacked device 100 can include three of more chips, which are vertically stacked on top of each other (e.g., vertically or in the z-direction). In the example of FIG. 1, stacked device 100 includes chip 110, chip 130 bonded to chip 110, and chip 150 bonded to chip 130. In particular, chip 150 can be a sensor chip including an array of optical sensors for collecting optical signals and generating optically excited charge carriers, chip 130 under chip 150 can be a pixel chip including pixel transistors that transform the optical signals into electrical signals, and chip 110 can be an image signal processing chip including an image processing unit for processing the electrical signals to generate digital images.

In some embodiments, chips 110, 130, and 150 can be formed on substrates 112, 132, and 152, respectively. Each of substrates 112, 132, and 152 can include a semiconductor material, such as silicon. In some embodiments, each of substrates 112, 132, and 152 can include a crystalline silicon substrate (e.g., wafer). In some embodiments, each of substrates 112, 132, and 152 can include (i) an elementary semiconductor, such as silicon (Si) or germanium (Ge); (ii) a compound semiconductor including silicon carbide (SiC), gallium arsenide (GaAs), gallium phosphide (GaP), indium phosphide (InP), indium arsenide (InAs), and/or indium antimonide (InSb); (iii) an alloy semiconductor including silicon germanium carbide (SiGeC), silicon germanium (SiGe), gallium arsenic phosphide (GaAsP), gallium indium phosphide (InGaP), gallium indium arsenide (InGaAs), gallium indium arsenic phosphide (InGaAsP), aluminum indium arsenide (InAlAs), and/or aluminum gallium arsenide (AlGaAs); or (iv) a combination thereof. Further, each of substrates 112, 132, and 152 can be doped depending on design requirements (e.g., p-type substrate or n-type substrate). In some embodiments, each of substrates 112, 132, and 152 can be doped with p-type dopants (e.g., boron (B), indium (In), aluminum (Al), or gallium (Ga)) or n-type dopants (e.g., phosphorus (P), arsenic (As), or antimony (Sb)). In some embodiments, crystal orientations of substrates 112, 132, and 152 can be (100), (110), or (111). In some embodiments, substrates 112, 132, and 152 can be the same type of substrate. In some embodiments, substrates 112, 132, and 152 can be different types of substrates.

In some embodiments, substrates 112, 132, and 152 can be thinned (e.g., mechanically grinded and polished)—prior to bonding chips 110, 130, and 150 together—to reduce the height of stacked device 100 and to facilitate the formation of electrically conductive structures that electrically connect the chips within stacked device 100. In some embodiments, 112, 132, and 152 are not thinned prior to bonding chips 110, 130, and 150 together. By way of example and not limitation, chips 110, 130, and 150 are aligned based on alignment marks (not shown) and subsequently bonded to bonding layers (passivation layers) and structures that mechanically secure and electrically connect the chips together. Bonding layers can include, for example, passivation layers with plasma-treated or chemically-treated surfaces and bonding structures with hybrid bonding structures (e.g., metal structures on adjoining surfaces inlaid in a dielectric material). As shown in FIG. 1, bonding pads 159 on a lower surface of chip 150 can be aligned and bonded with bonding pads 149 on an upper surface of chip 130. Similarly, bonding pads 148 on a lower surface of chip 130 can be aligned and bonded with bonding pads 128 on an upper surface of chip 110.

Referring to FIG. 1, chip 150 can be a chip of an image sensor including an array of optical sensors 160 in substrate 152. For example, array of optical sensors 160 can include a matrix of m rows by n columns pixels, such that a resolution of the image sensor is m×n. In some embodiments, each pixel can include a photo-sensing region 162 through substrate 152, a filter 164 on a first side of substrate 152 and aligned with photo-sensing region 162, and a lens 166 on filter 164. In some embodiments, lenses 166 can be micro-lenses and can have curved surfaces to facilitate collecting and focusing incident optical signals. In some embodiments, filters 164 can have the same or different optical transmission spectra to select optical signals within particular ranges of wavelengths. For example, filters 164 can include filters that allow different colors (e.g., red, green, or blue) to transmit. In some embodiments, photo-sensing regions 162 can be intrinsic or doped with a desired doping profile. For example, each photo-sensing region 162 can have a structure of a p-i-n diode. In some embodiments, each pixel can further include a transistor 156 on a second side of substrate 152 and adjacent to photo-sensing region 162. Transistors 156 can include metal oxide semiconductor field effect transistors (MOSFETs), such as planar MOSFETS, fin field effect transistors (FinFETs), complementary fin field effect transistors (CFETs), gate-all-around field effect transistors (GAAFETs) and/or vertical fin field effect transistors (VFETs). Incident photons collected by lenses 166 and filtered by filters 164 can excite charge carriers in photo-sensing regions 162. These photo-excited charge carriers can be collected by transistors 156. Chip 150 can further include a dielectric layer 154 on the second side of substrate 152. An interconnect structure 158 can be embedded in dielectric layer 154 that couples transistors 156 and bonding pads 159 to provide the photo-excited charge carriers to chip 130. In some embodiments, interconnect structure 158 can include conductive lines and conductive vias made of conductive materials, such as titanium, cobalt, aluminum, copper, tungsten, tantalum, nickel, ruthenium, other suitable metals, and/or a combination thereof.

Referring to FIG. 1, chip 110 can be a chip of an image signal processor (ISP) including transistors 116 disposed on substrate 112. Transistors 116 can be part of a processing unit that generates the digital images from electrical signals provided by chip 130. Transistors 116 can also be referred to as ISP transistors 116. Transistors 116 can include MOSFETs, such as FinFETs, GAAFETs, CFETs, and/or VFETs. Chip 110 can further include a dielectric layer 114 disposed on transistors 116. An interconnect structure 118 can be embedded in dielectric layer 114 that couples transistors 116 and bonding pads 128 to communicate with chip 130. In some embodiments, interconnect structure 118 can include conductive lines and conductive vias made of conductive materials, such as titanium, cobalt, aluminum, copper, tungsten, tantalum, nickel, ruthenium, other suitable metals, and/or a combination thereof.

Referring to FIG. 1, chip 130 can include transistors 136 disposed on substrate 132 and providing electrical signals corresponding to the pixels of array of optical sensors 160 in chip 150. Transistors 136 can also be referred to as pixel transistors 136. Transistors 136 can include MOSFETs, such as FinFETs, GAAFETs, CFETs, and/or VFETs. Chip 130 can further include a dielectric layer 134 disposed on transistors 136. An interconnect structure 138 can be embedded in dielectric layer 134 that couples transistors 136 and bonding pads 149 to communicate with chip 150. In some embodiments, interconnect structure 138 can include conductive lines and conductive vias made of conductive materials, such as titanium, cobalt, aluminum, copper, tungsten, tantalum, nickel, ruthenium, other suitable metals, and/or a combination thereof.

In some embodiments, chip 130 can further include dummy transistors 140 disposed on substrate 132. Dummy transistors 140 can be formed on regions of substrate 132 that are not occupied by pixel transistors 136. In some embodiments, during a manufacturing process of fabricating dielectric layer 134 and interconnect structure 138 on substrate 132, the presence of dummy transistors 140 on substrate 132 can adequately mitigate potential dishing problem due to a loading effect during a planarization process. Dummy transistors 140 do not participate processing the electrical signals. In some embodiments, dummy transistors 140 can be formed during the manufacturing process of forming pixel transistors 136. However, dummy transistors 140 can be either partially formed or completely formed. For example, dummy transistors 140 can include only source/drain regions epitaxially grown together with the growth of source/drain regions of pixel transistors 136. In another example, dummy transistors 140 can include only gate structures formed with gate structures of pixel transistors 136. In some embodiments, dummy transistors 140 can include both the source/drain regions and the gate structures. In some embodiments, the source/drain regions and/or the gate structures can be electrically coupled with pixel transistors 136 via buried contacts 135, which are conductive lines buried in dielectric layer 134 and at the same horizontal level as dummy transistors 140 and pixel transistors 136. In some embodiments, buried contacts 135 can be made of conductive materials similar to those included in interconnect structure 138. In some embodiments, buried contacts 135 can also be conductive lines formed by in substrate 132 by selectively doping strips of substrate 132 that connects dummy transistors 140 and pixel transistors 136.

In some embodiments, chip 130 can further include through-silicon vias (TSVs) 146 through substrate 132 and electrically coupling dummy transistors 140 and bonding pad 148, such that electrical connections between pixel transistors 136 and ISP transistors 116 can be established. In some embodiments, TSVs 146 can have a vertical length substantially the same as a thickness of substrate 132. In some embodiments, each TSV 146 can have a horizontal width expanding over multiple dummy transistors 140. In some embodiments, TSVs 146 can have an aspect ratio (a ratio of their vertical length to their horizontal width) between about 10 and about 1000. TSVs 146 can be made of conductive materials, such as titanium, cobalt, aluminum, copper, tungsten, tantalum, nickel, ruthenium, other suitable metals, and/or a combination thereof. In some embodiments, each TSV 146 can be in contact with an array of dummy transistors 140. By electrically coupling to pixel transistors 136 via dummy transistors 140 instead of interconnect structure 138 above the pixel transistors 136, TSVs 146 as shown in FIG. 1 can reduce lengths of current paths between pixel transistors 136 and ISP transistors 116, such that the RC delay can be reduced and the operating speed of stacked device 100 can be improved.

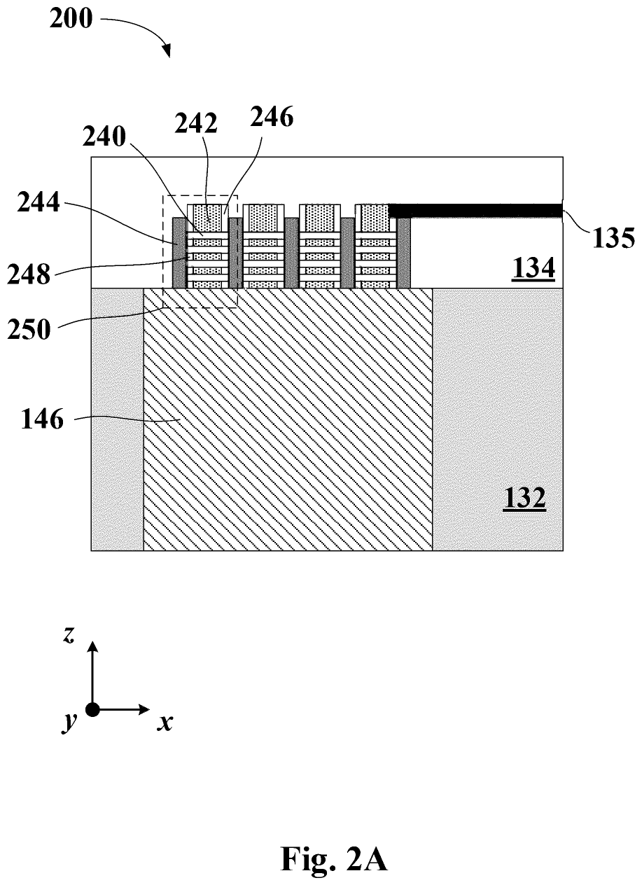

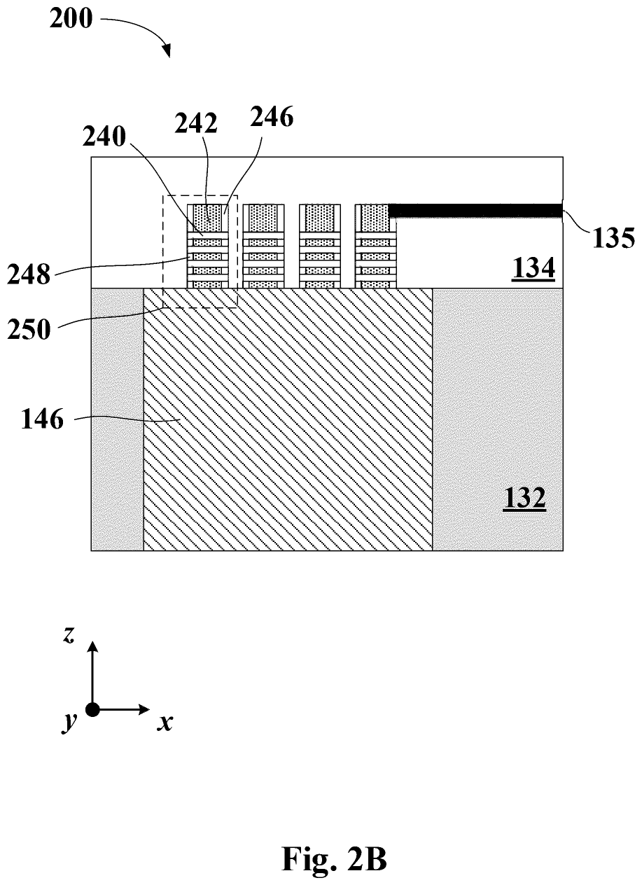

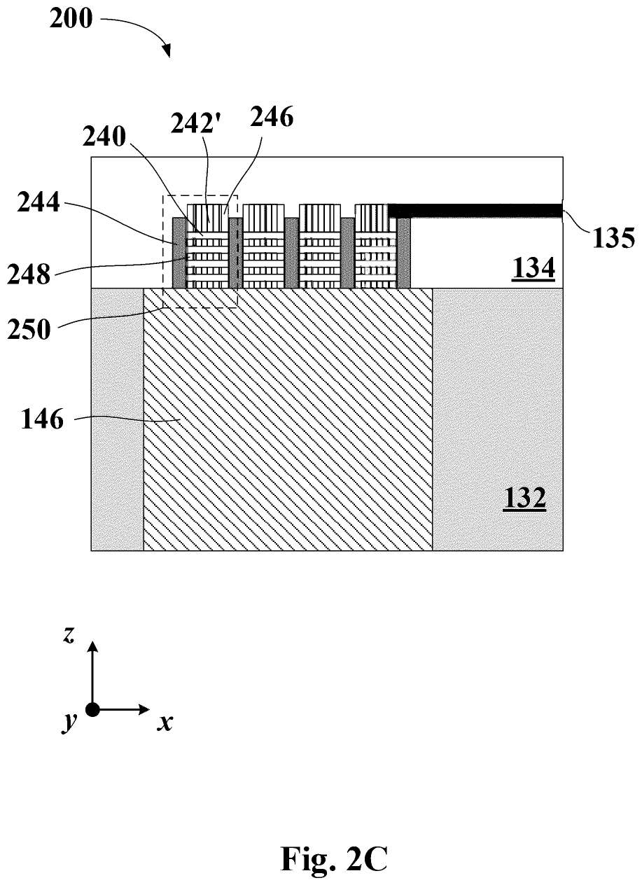

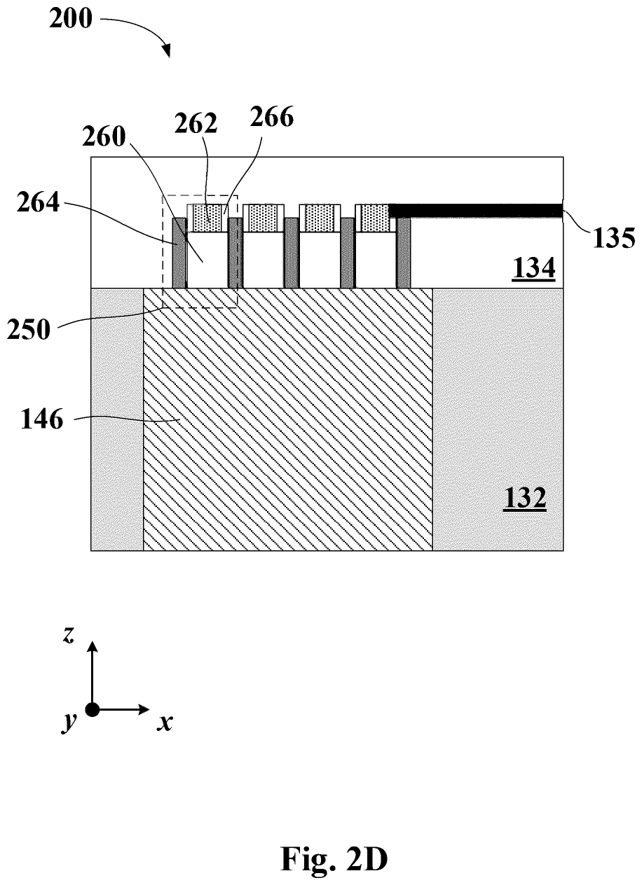

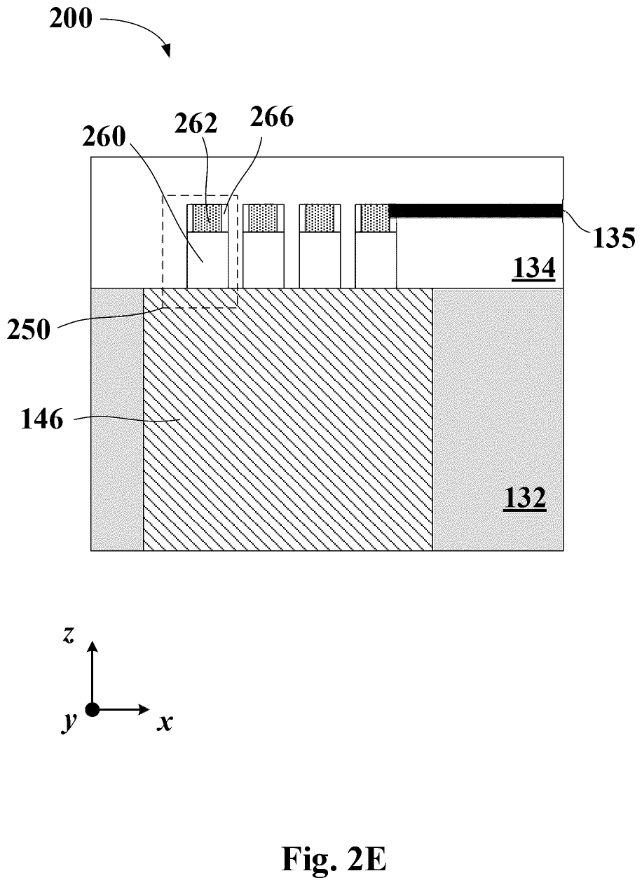

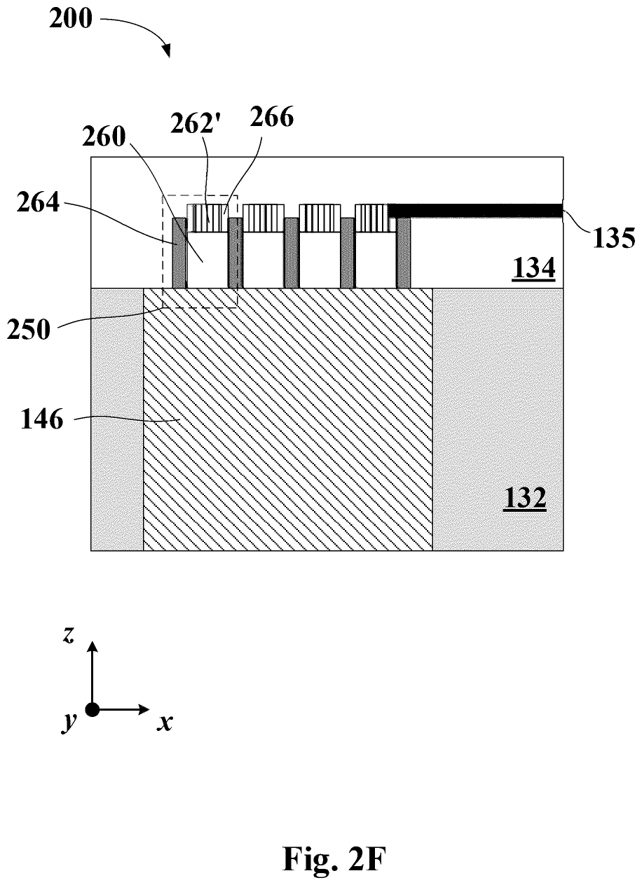

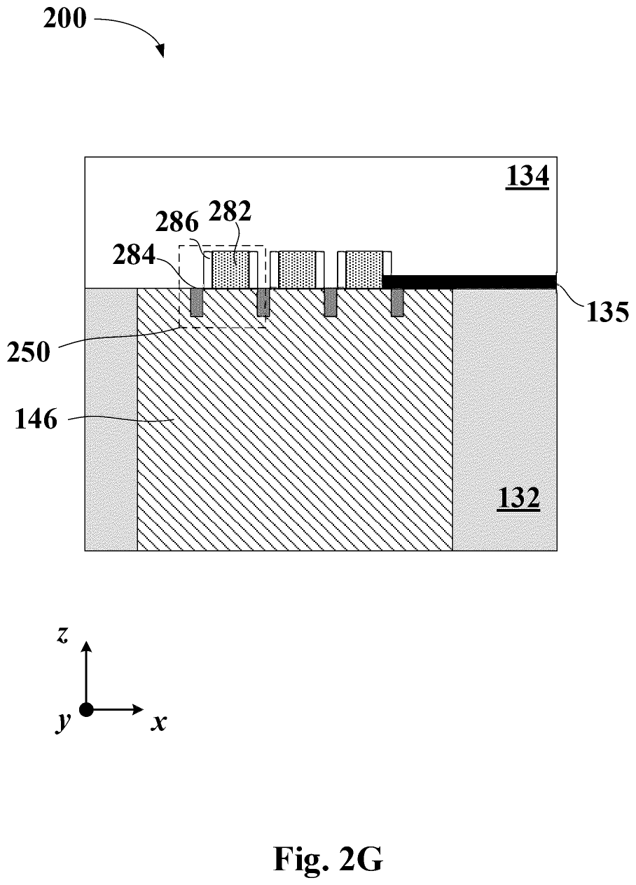

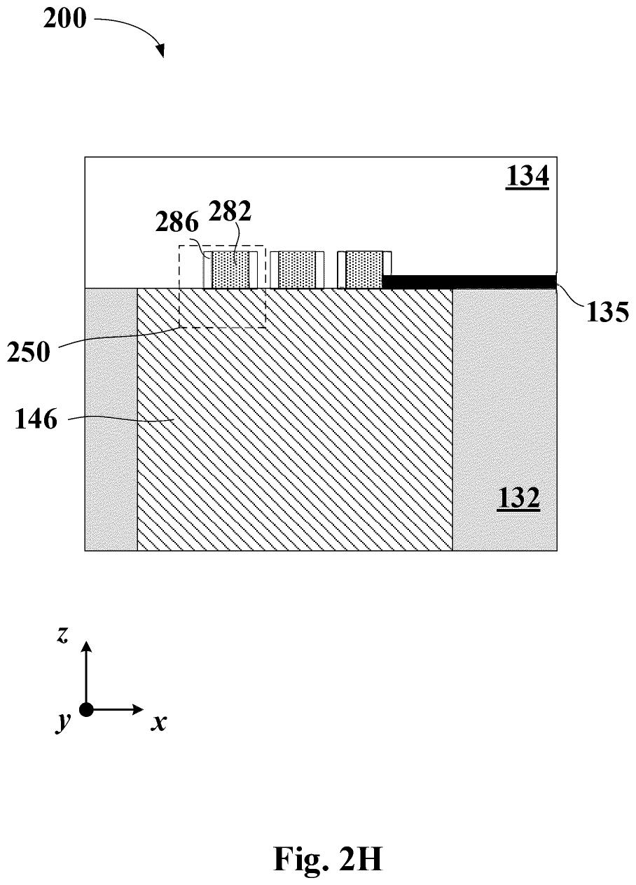

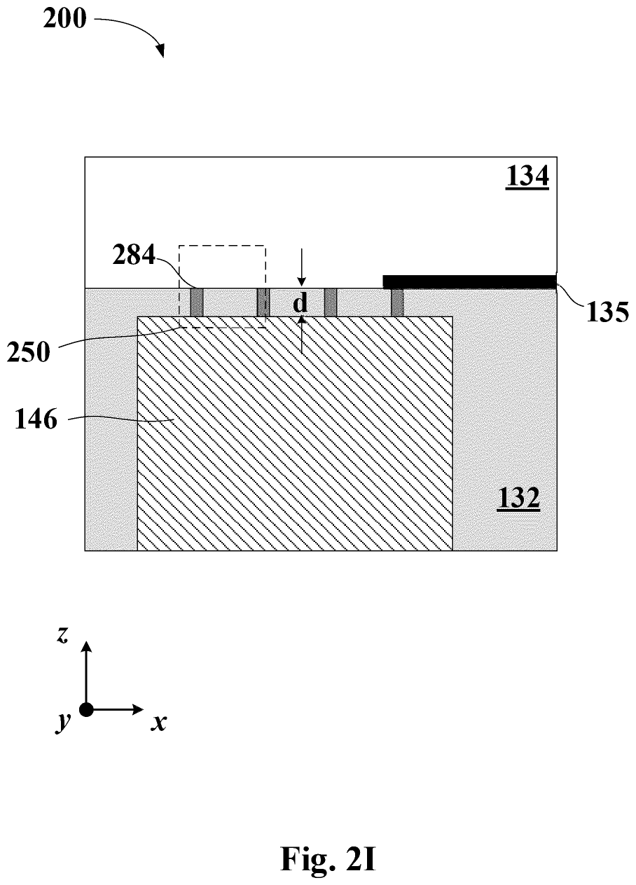

As mentioned above, dummy transistors 140 can include different types to transistors, and can be partially or completely formed. Accordingly, there are different schemes to couple dummy transistors 140 and TSVs 146, as shown in FIGS. 2A-2I as embodiments of a zoomed-in portion 200 of s tacked device 100 in FIG. 1. The discussion of elements in FIG. 1 with the same annotations applies to FIGS. 2A-2I, unless mentioned otherwise.

Zoomed-in portion 200 can include a number of dummy transistors 250. As shown in FIG. 2A, dummy transistors 250 can be GAAFETs, each including nanostructures 240 (e.g., nanosheets or nanowires) as channels. In some embodiments, dummy transistor 250 can include a gate structure 242, which can include work function metal layers and gate electrodes surrounding nanostructures 240. In some embodiments, gate structure 242 can include conductive materials, such as titanium nitride, tantalum nitride, tungsten nitride, titanium, aluminum, copper, tungsten, tantalum, cobalt, nickel, or a combination thereof. Dummy transistor 250 can also include source/drain regions 244, which can be epitaxial layers grown from substrate 132 and/or nanostructures 240. In some embodiments, source/drain regions 244 can include a semiconductor material, such as silicon or silicon germanium. In some embodiments, a germanium concentration of source/drain regions 244 can be within a first range of about 15% to about 25%. In some embodiments, a germanium concentration of source/drain regions 244 can be within a second range of about 25% to about 60%. In some embodiments, source/drain regions 244 can be doped as p-type and/or n-type to be conductive. For example, source/drain regions 244 can include phosphorous dopants with a concentration between about 1×10²⁰ cm⁻³ and about 1×10²² cm⁻³. In some embodiments, dummy transistor 250 can further include spacer structures 246 and inner spacer structures 248 separating gate structure 242 and source/drain regions 244. Gate structures 242 and/or source/drain regions 244 can be in direct contact with TSV 146 to electrically couple with ISP transistors 116 on chip 110 as shown in FIG. 1. One or more of gate structures 242 and/or source/drain regions 244 can be in direct contact with buried contact 135 to electrically couple with pixel transistors 136 on substrate 132 as shown in FIG. 1.

In some embodiments, dummy transistor 250 may be partially formed and can include some but not all of the elements shown in FIG. 2A. For example, as shown in FIG. 2B, dummy transistor 250 can include nanostructures 240, gate structure 242, spacer structures 246, and inner spacer structures 248 without source/drain regions 244, in comparison with FIG. 2A. Since dummy transistor 140 and pixel transistors 136 as shown in FIG. 1 can be formed in the same manufacturing process, embodiments of dummy transistors 250 in FIG. 2B can be formed by inhibiting the epitaxial growth of semiconductor materials on exposed surfaces of nanostructures 240 and substrate 132 while growing the source/drain regions of pixel transistors 136. Other than the absence of source/drain regions 244, the discussion of other elements in FIG. 2B with the same annotations are the same as in FIG. 2A and is not repeated for simplicity.

In some embodiments, some of the elements of dummy transistors 250 can be different from those shown in FIG. 2A. For example, as shown in FIG. 2C, dummy transistors 250 can include dummy gate structure 242′. Different from gate structures 242 including conductive materials as shown in FIGS. 2A and 2B, dummy gate structure 242′ can include silicon germanium sacrificial layers stacked with nanostructures 240 and polysilicon sacrificial layer on nanostructures 240. As mentioned above, dummy transistors 140 and pixel transistors 136 as shown in FIG. 1 can be formed as GAAFETs in the same manufacturing process, in which dummy gate structures can be intermediately formed to surround the channel layers of both dummy transistors 140 and pixel transistors 136, and only the dummy gate structures of pixel transistors 136 are subsequently replaced by gate structures, leaving dummy gate structure 242′ remaining on dummy transistors 140/250, as shown in FIG. 2C. Other than dummy gate structure 242′, the discussion of other elements in FIG. 2C with the same annotations are the same as in FIG. 2A and is not repeated for simplicity.

In some embodiments, as shown in FIG. 2D, dummy transistors 250 can be finFETs, each including a fin structure 260 as a channel. In some embodiments, fin structure 260 can include a semiconductor material similar to that of substrate 132. In some embodiments, dummy transistor 250 can include a gate structure 262, which can include work function metal layers and gate electrodes on top and side surfaces of fin structure 260. In some embodiments, gate structure 262 can include conductive materials, such as titanium nitride, tantalum nitride, tungsten nitride, titanium, aluminum, copper, tungsten, tantalum, cobalt, nickel, or a combination thereof. Dummy transistor 250 can also include source/drain regions 264, which can be epitaxial layers grown from substrate 132 and/or fin structure 260. In some embodiments, source/drain regions 264 can include a semiconductor material, such as silicon or silicon germanium. In some embodiments, a germanium concentration of source/drain regions 264 can be within a first range of about 15% to about 25%. In some embodiments, a germanium concentration of source/drain regions 264 can be within a second range of about 25% to about 60%. In some embodiments, source/drain regions 264 can be doped as p-type and/or n-type to be conductive. For example, source/drain regions 264 can include phosphorous dopants with a concentration between about 1×10²⁰ cm⁻³ and about 1×10²² cm⁻³. In some embodiments, dummy transistor 250 can further include spacer structures 266 separating gate structure 262 and source/drain regions 264. Gate structures 262 and/or source/drain regions 264 can be in direct contact with TSV 146 to electrically couple with ISP transistors 116 on chip 110 as shown in FIG. 1. One or more of gate structures 262 and/or source/drain regions 264 can be in direct contact with buried contact 135 to electrically couple with pixel transistors 136 on substrate 132 as shown in FIG. 1.

In some embodiments, dummy transistor 250 may be partially formed and can include some but not all of the elements shown in FIG. 2D. For example, as shown in FIG. 2E, dummy transistor 250 can include fin structures 260, gate structure 262, and spacer structures 266 without source/drain regions 264, in comparison with FIG. 2D. Since dummy transistor 140 and pixel transistors 136 as shown in FIG. 1 can be formed in the same manufacturing process, embodiments of dummy transistors 250 in FIG. 2E can be formed by inhibiting the epitaxial growth of source/drain regions on exposed surfaces of fin structures 260 and substrate 132 while growing the source/drain regions of pixel transistors 136. Other than the absence of source/drain regions 264, the discussion of other elements in FIG. 2E with the same annotations are the same as in FIG. 2D and is not repeated for simplicity.

In some embodiments, some of the elements of dummy transistors 250 can be different from those shown in FIG. 2D. For example, as shown in FIG. 2F, dummy transistors 250 can include dummy gate structure 262′. Different from gate structures 262 including conductive materials as shown in FIGS. 2D and 2E, dummy gate structure 242′ can include a polysilicon sacrificial layer on fin structure 260. As mentioned above, dummy transistors 140 and pixel transistors 136 as shown in FIG. 1 can be formed as finFETs in the same manufacturing process, in which dummy gate structures can be intermediately formed to surround the fin structures of both dummy transistors 140 and pixel transistors 136, and only the dummy gate structures in pixel transistors 136 are subsequently replaced by gate structures, leaving dummy gate structure 262′ remaining on dummy transistors 140/250, as shown in FIG. 2F. Other than dummy gate structure 262′, the discussion of other elements in FIG. 2F with the same annotations are the same as in FIG. 2D and is not repeated for simplicity.

In some embodiments, as shown in FIG. 2G, dummy transistors 250 can be planar FETs, each including a gate structure 282, gate spacers 286 on gate structure 282, and source/drain regions 284 adjacent to gate spacers 286. Gate structure 282 can include work function metal layers and gate electrodes. In some embodiments, gate structure 282 can include conductive materials, such as titanium nitride, tantalum nitride, tungsten nitride, titanium, aluminum, copper, tungsten, tantalum, cobalt, nickel, or a combination thereof. Source/drain regions 284 can be doped regions in substrate 132. In some embodiments, source/drain regions 284 can be doped as p-type and/or n-type to be conductive. For example, source/drain regions 284 can include phosphorous dopants with a concentration between about 1×10²⁰ cm⁻³ and about 1×10²² cm⁻³. Gate structures 282 and/or source/drain regions 284 can be in direct contact with TSV 146 to electrically couple with ISP transistors 116 on chip 110 as shown in FIG. 1. One or more of gate structures 282 and/or source/drain regions 284 can be in direct contact with buried contact 135 to electrically couple with pixel transistors 136 on substrate 132 as shown in FIG. 1.

In some embodiments, dummy transistor 250 may be partially formed and can include some but not all of the elements shown in FIG. 2G. For example, as shown in FIG. 2H, dummy transistor 250 can include gate structure 282 and gate spacers 286 without source/drain regions 284, in comparison with FIG. 2G. Since dummy transistor 140 and pixel transistors 136 as shown in FIG. 1 can be formed in the same manufacturing process, embodiments of dummy transistors 250 in FIG. 2H can be formed by inhibiting the formation of source/drain regions in substrate 132 while forming the source/drain regions of pixel transistors 136. Other than the absence of source/drain regions 284, the discussion of other elements in FIG. 2H with the same annotations are the same as in FIG. 2G and is not repeated for simplicity.

In some embodiments, different from FIGS. 2G and 2H, dummy transistors 250 can include source/drain regions 284 without gate structure 282 and gate spacers 286, as shown in FIG. 2I. As mentioned above, dummy transistors 140 and pixel transistors 136 as shown in FIG. 1 can be formed as finFETs in the same manufacturing process, in which gate structures can be selectively formed only for pixel transistors 136, such that dummy transistors 140/250 do not include gate structures, as shown in FIG. 2F. In some embodiments, since source/drain regions 284 are in substrate 132, TSV 146 can be in contact with bottom surfaces of source/drain regions 284 without having to penetrate through the entire thickness of substrate 132. For example, as shown in FIG. 2I, a distance d between an upper surface of TSV 146 and an upper surface of substrate 132 can be between about 50 nm and about 500 nm. The discussion of other elements in FIG. 2I with the same annotations are the same as in FIG. 2G unless mentioned otherwise.

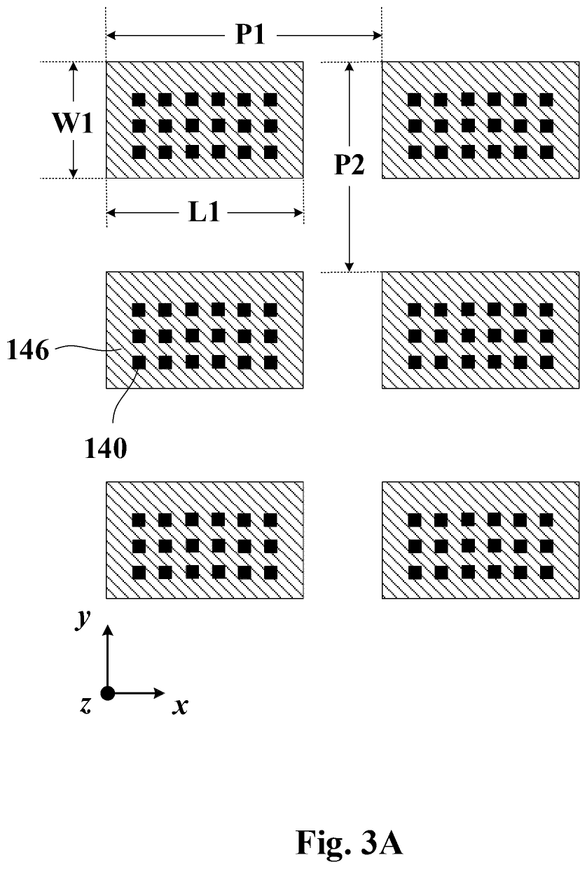

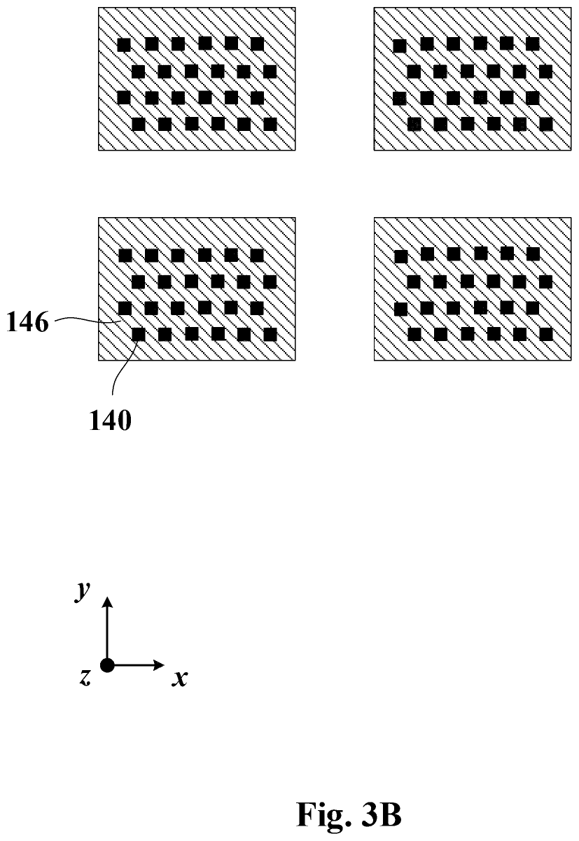

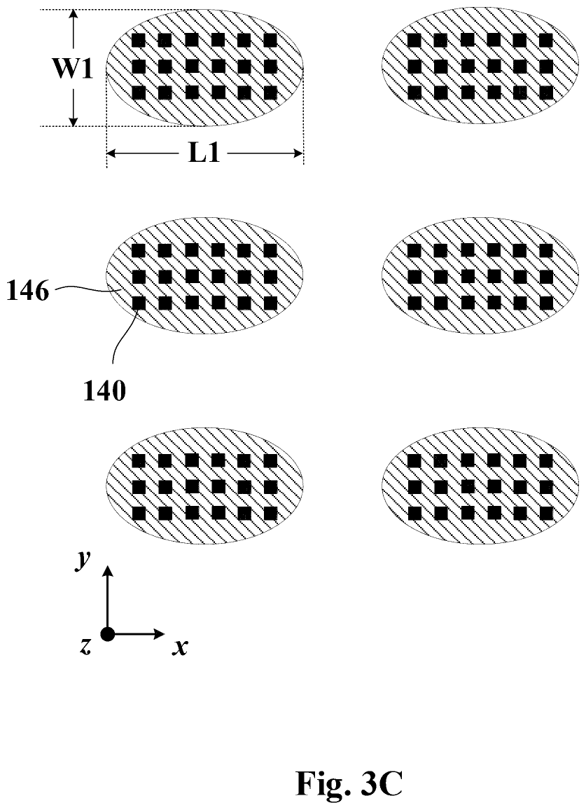

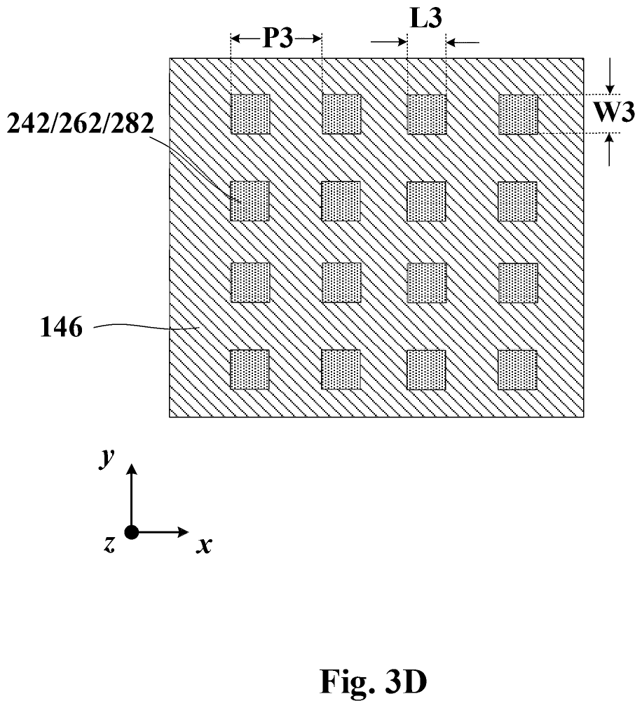

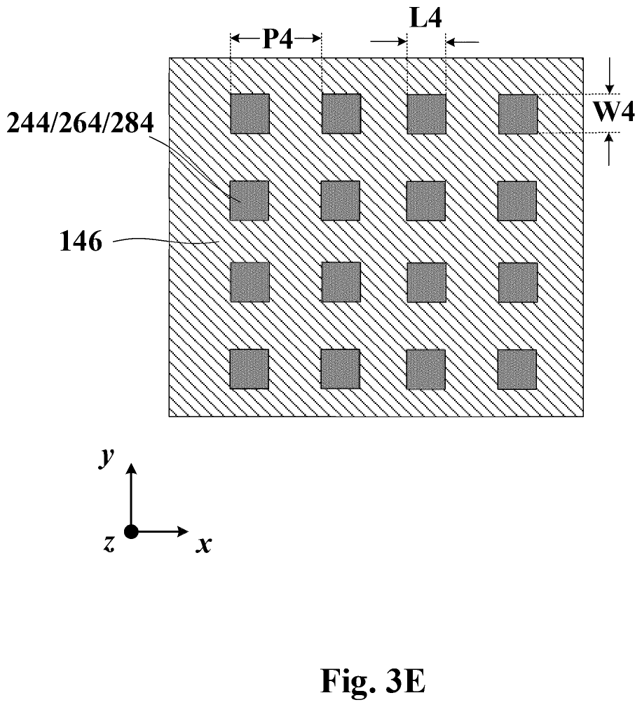

Although FIG. 1 shows that chip 130 includes two TSVs 146, each coupled to three or four dummy transistors 140, it should be understandable that chip 130 can include any number of TSVs 146, and each TSV 146 can be coupled to any number of dummy transistors 140. FIGS. 3A-3C are plan views of chip 130 illustrating embodiments of an array of TSVs 146 each coupled to an array of dummy transistors 140. FIGS. 3D and 3E are plan views illustrating individual TSV 146 coupled to an array of dummy transistors 140. The discussion of elements in FIGS. 1-2I with the same annotations applies to FIGS. 3A-3E, unless mentioned otherwise.

Referring to FIG. 3A, each of TSVs 146 can have a rectangular cross section with a width W1 and a length L1 along horizontal directions (e.g., along the x and y axes). In some embodiments, width W1 and length L1 can be between about 1 μm and about 300 μm. In some embodiments, width W1 and length L1 can be substantially the same, such that TSVs 146 are of square shapes. In some embodiments, width W1 and length L1 can be different. For example, width W1 can be greater than about 1 μm and length L1 can be greater than about 2 μm. In some embodiments, the array of TSVs 146 can have their edges aligned with each other. In some embodiments, the array of TSVs 146 can have periodic translation symmetry with pitches P1 and P2 along the horizontal directions (e.g., along the x and y axes). In some embodiments, pitches P1 and P2 can be between about 2 μm and about 500 μm. In some embodiments, pitches P1 and P2 can be substantially the same. In some embodiments, pitches P1 and P2 can be different. In some embodiments, the array of TSVs 146 can be disposed without periodic translation symmetry.

Referring to FIGS. 3A and 3B, although FIG. 3A shows that each TSV 146 couples to an array 3×6 dummy transistors 140, and FIG. 3B shows that each TSV 146 couples to an array of 4×6 dummy transistors 140, it should be understood that the array can include any number of rows and columns of dummy transistors 140. In some embodiments, dummy transistors 140 within the array can have their edges aligned with each other, as shown in FIG. 3A. In some embodiments, dummy transistors 140 within the array can have their edges offset with each other, as shown in FIG. 3B.

In some embodiments, as shown in FIG. 3C, each of TSVs 146 can have an elliptical cross section with a width W1 and a length L1 along horizontal directions (e.g., along the x and y axes). In some embodiments, width W1 and length L1 can be different. In some embodiments, width W1 and length L1 can be substantially the same, such that the cross section of TSV 146 is circular.

In some embodiments, TSV 146 can be coupled to an array of gate structures 242/262/282 of dummy transistors 140, as shown in FIG. 3D. In some embodiments, a pitch P3 of gate structures 242/262/282 in the array can be greater than about 50 nm. In some embodiments, each of gate structures 242/262/282 can have a length L3 and a width W3 along the horizontal directions (e.g., along the x and y axes). In some embodiments, length L3 and width W3 can be greater than about 10 nm. In some embodiments, length L3 and width W3 can be substantially the same. In some embodiments, length L3 and width W3 can be different. In some embodiments, a ratio between length L1 or width L1 to length L3 or width W3 can be between about 10 and about 15,000.

In some embodiments, TSV 146 can be coupled to an array of source/drain regions 244/264/284 of dummy transistors 140, as shown in FIG. 3E. In some embodiments, a pitch P4 of source/drain regions 244/264/284 in the array can be greater than about 50 nm. In some embodiments, each of source/drain regions 244/264/284 can have a length L4 and a width W4 along the horizontal directions (e.g., along the x and y axes). In some embodiments, length L4 and width W4 can be greater than about 30 nm. In some embodiments, length L4 and width W4 can be substantially the same. In some embodiments, length L4 and width W4 can be different. In some embodiments, a ratio between length L1 or width L1 to length L4 or width W4 can be between about 10 and about 10,000.

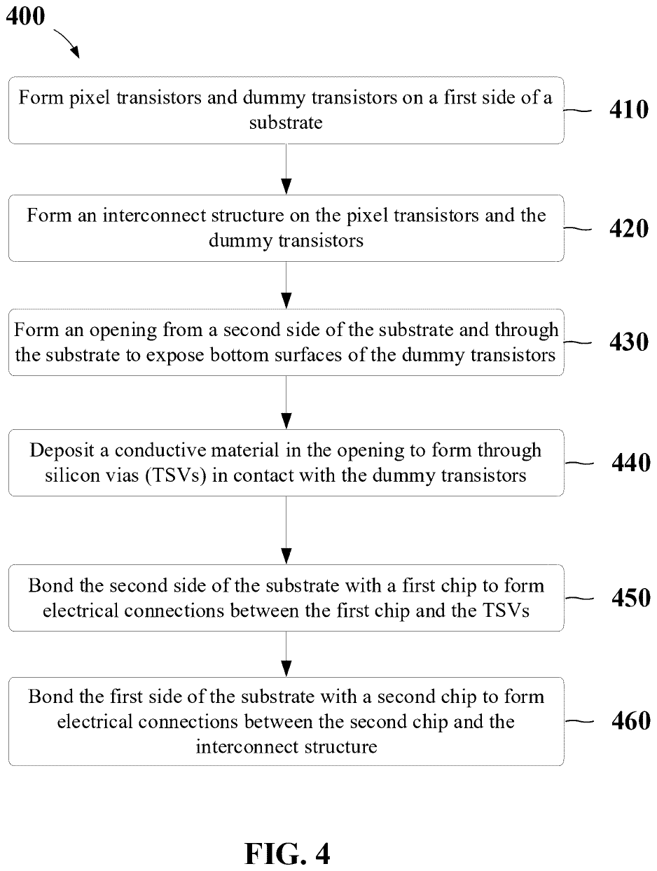

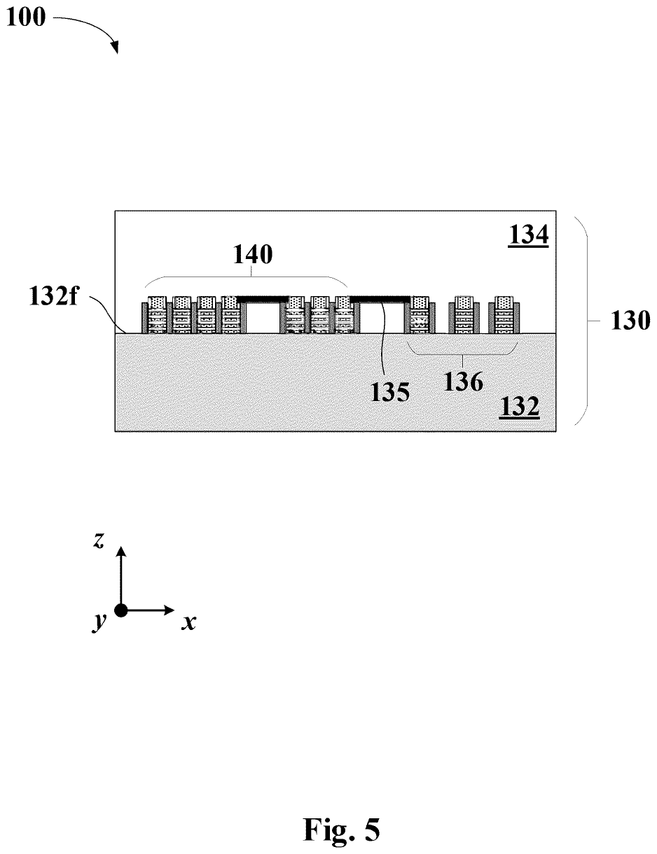

According to some embodiments, FIG. 4 illustrates a flowchart of a fabrication method 400 for the formation of stacked device 100 shown in FIG. 1. This disclosure is not limited to this operational description and additional operations may be performed. Other fabrication operations can be performed between the various operations of method 400 and are omitted merely for clarity. Moreover, not all operations may be needed to perform the disclosure provided herein. Additionally, some of the operations may be performed simultaneously, or in a different order than the ones shown in FIG. 4. In some embodiments, one or more other operations may be performed in addition to or in place of the presently described operations. For illustrative purposes, method 400 is described with reference to the structures shown in FIGS. 5-10. The discussion of elements in FIGS. 1-3E with the same annotations applies to FIGS. 5-10, unless mentioned otherwise.

Referring to FIG. 4, method 400 begins with operation 410 and the process of forming pixel transistors and dummy transistors on a first side of a substrate. For example, as described with reference to FIG. 5, pixel transistors 136 and dummy transistors 140 are formed on a front surface 132f of substrate 132. In some embodiments, forming pixel transistors 136 can include forming GAAFETs, finFETs, planar MOSFETs, or a combination on front surface 132f of substrate 132. For example, forming pixel transistors 136 can include forming different elements of pixel transistors 136, such as channel layers, gate structures, spacer structures, and source/drain structures. In some embodiments, dummy transistors 140 can be formed in the same manufacturing process of forming pixel transistors 136. As described above, in some embodiments, dummy transistors 140 can include all of the elements of pixel transistors 136. In some embodiments, dummy transistors 140 include some but not all of the elements of pixel transistors 136 (e.g., dummy transistors 140 include the source/drain regions but not the gate structures, or vice versa, as described with reference to FIGS. 2A-2I). During the process of forming certain elements in pixel transistors 136 without having them formed in dummy transistors 140, dummy transistors 140 can be isolated (e.g., covered by a mask) from the process. In some embodiments, buried contact 135 can be formed by depositing conductive lines in contact with some of dummy transistors 140 and pixel transistors 136. In some embodiments, dielectric layer 134 can be formed on dummy transistors 140 and pixel transistors 136 by depositing a layer of dielectric material.

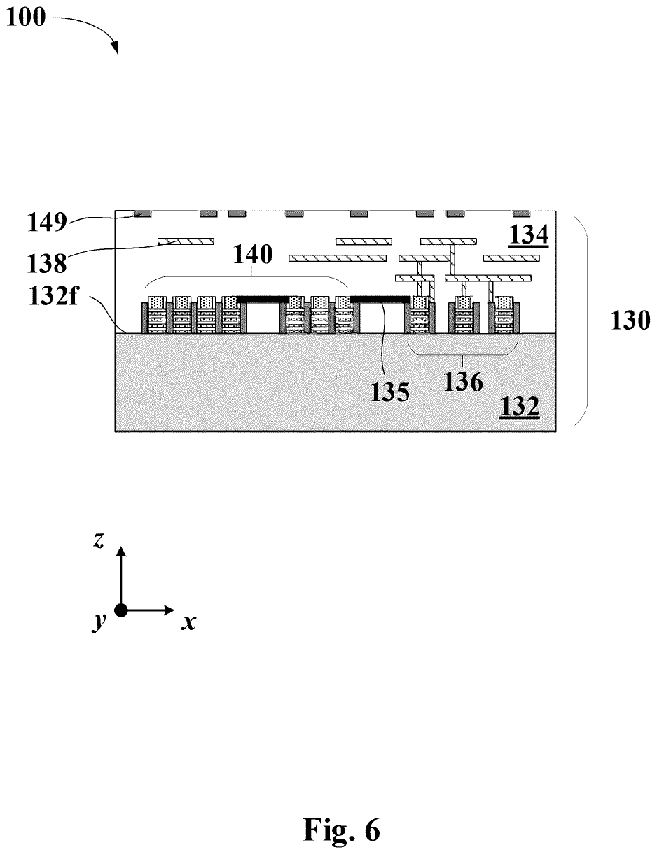

Referring to FIG. 4, method 400 can continue with operation 420, in which an interconnect structure can be formed on the pixel transistors and the dummy transistors. For example, as described with reference to FIG. 6, interconnect structure 138 can be formed in dielectric layer 134 and electrically couple with gate structures and/or source/drain regions of pixel transistors 136. In some embodiments, forming interconnect structure 138 can include etching dielectric layer 134 to form via openings and line openings and depositing conductive materials in the via openings and line openings to interconnect pixel transistors 136. In some embodiments, bonding pads 149 can be formed on a top surface of dielectric layer 134 and in contact with interconnect structure 138. Forming bonding pads 149 can include etching dielectric layer 134 to form pad openings and deposit conductive materials in the pad opening, followed by a planarization process (e.g., a chemical mechanical polishing process) on the top surface of dielectric layer 134. The presence of dummy transistors 140 can adequately mitigate potential dishing problem due to a loading effect during the planarization process.

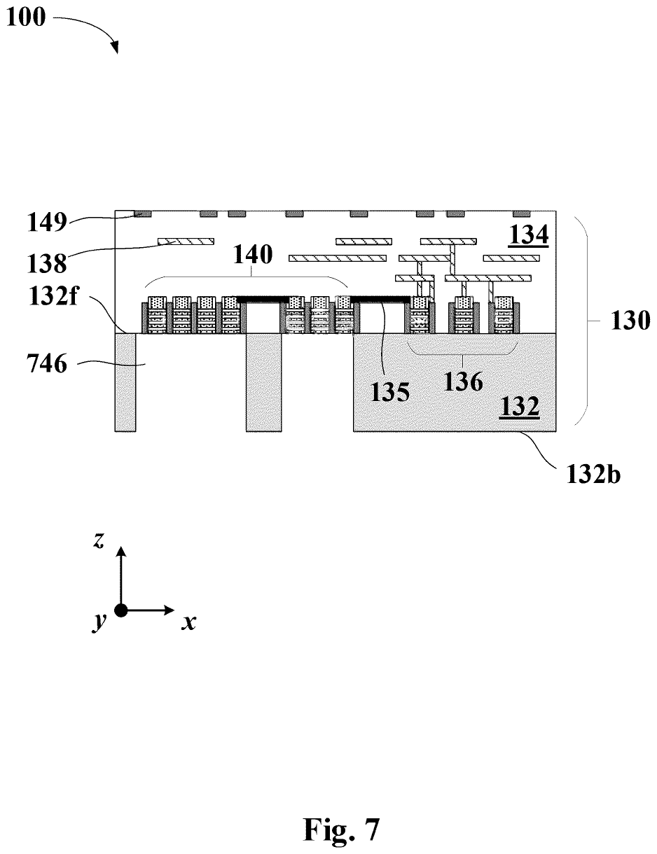

Referring to FIG. 4, method 400 can continue with operation 430, in which an opening can be formed from a second side of substrate and through the substrate to expose bottom surfaces of the dummy transistors. For example, as described with reference to FIG. 7, openings 746 can be formed through substrate 132 to expose bottom surfaces of the source/drain regions and/or gate structures of dummy transistors 140. In some embodiments, forming openings 746 can include etching a back surface 132b of substrate 132 in regions opposite to regions of dummy transistors 140 on front surface 132f. In some embodiments, the etching can last until substrate 132 has substantially been etched through to expose the bottom surfaces of the source/drain regions and/or gate structures of dummy transistors 140. In some embodiments, the etching process can include dry etching, wet etching, or a combination thereof. In some embodiments, etchants with selective etching orientations to substrate 132 can be use in the etching process.

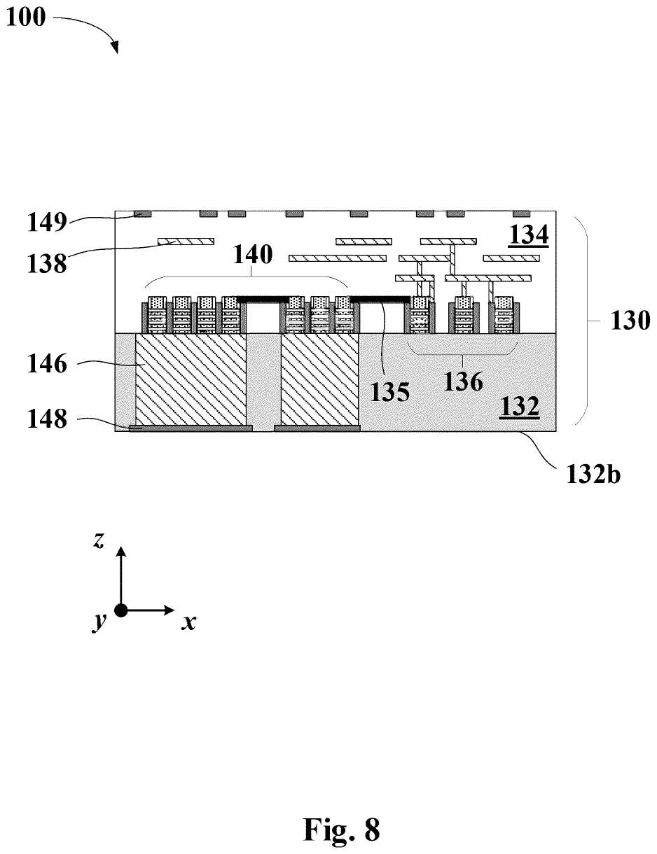

Referring to FIG. 4, method 400 can continue with operation 440, in which a TSV can be formed by depositing a conductive material in the opening. For example, as described with reference to FIG. 8, TSVs 146 can be formed in openings 746 in contact with bottom surfaces of the source/drain regions and/or gate structures of dummy transistors 140. In some embodiments, forming TSVs 146 can include depositing conductive materials in openings 746. In some embodiments, bonding pads 148 can be formed on back surface 132b of substrate 132 and in contact with TSVs 146. In some embodiments, forming bonding pads 148 can include depositing conductive materials on back sides of TSVs 146 and in substrate 132, follow by a planarization (e.g., by a chemical mechanical polishing process) of back surface 132b of substrate 132.

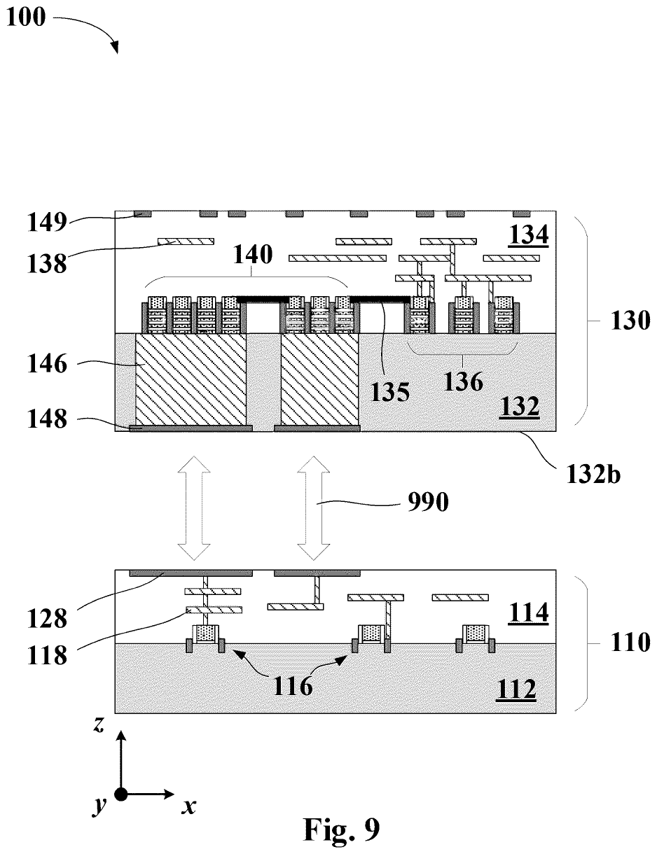

Referring to FIG. 4, method 400 can continue with operation 440, in which a first chip can be bonded to the second side of the substrate. For example, as described with reference to FIG. 9, chip 110 can be bonded to back surface 132b of substrate 132. The bonding process can include direct die stacking and die-to-die bonding, such as a hybrid bonding process that bonds chip 110 and chip 130 together. The bonding process can include aligning bonding pads 148 of chip 130 and bonding pads 128 of chip 110 to establish electrical connections between the two chips. The bonding process can also include an performing an annealing operation so that conductive materials of bonding pads 148 and 128 can migrate into each other to remove defects/vacancies between them and improve a quality of their electrical connections.

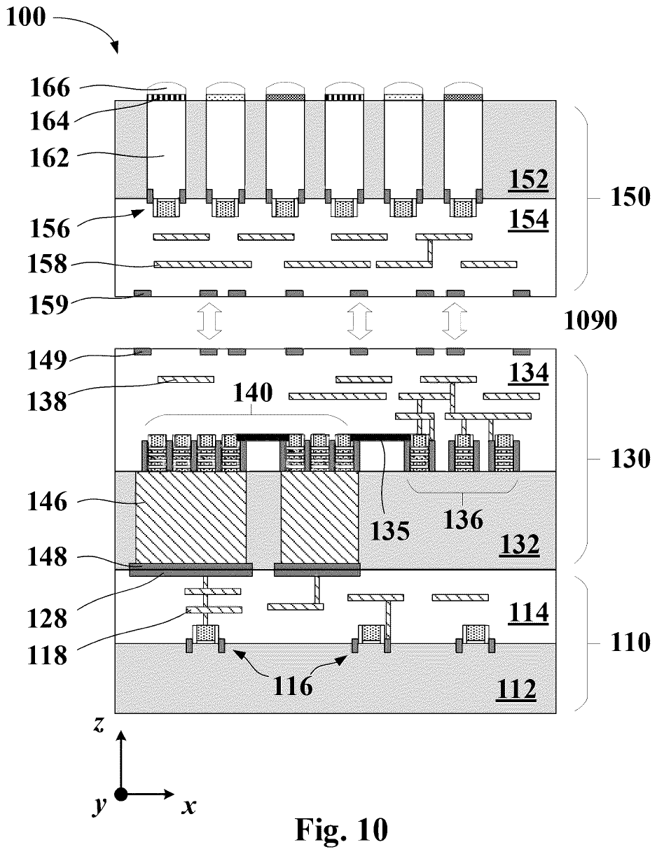

Referring to FIG. 4, method 400 can continue with operation 460, in which a second chip can be bonded to the first side of the substrate. For example, as described with reference to FIG. 10, chip 150 can be bonded to front surface 132f of substrate 132. The bonding process can be similar to the bonding process in operation 450, such as a hybrid bonding process that bonds chip 130 and chip 150 together. The bonding process can align bonding pads 149 of chip 130 and bonding pads 159 of chip 150 to establish electrical connections between the two chips. The bonding process can also include performing an annealing operation so that conductive materials of bonding pads 149 and 159 can migrate into each other to remove defects/vacancies between them and improve a quality of their electrical connections. After operation 460, stacked device 100 is completed with chips 110, 130, and 150 stacked together.

The embodiments described herein are directed to a structure of a semiconductor device and a method of forming the structure. The structure can include a substrate having active regions and dummy regions on a first side of the substrate. The active regions can include active transistors for normal operation of the semiconductor device, whereas the dummy regions can include dummy structures (such as dummy transistors) to avoid the problem of dishing due to the loading effect during manufacturing the structure. The dummy structures can electrically couple to the active transistors via buried contacts in the substrate. The structure can further include a chip bonded to a second side of the substrate and TSVs in contact with the dummy structures and a bonding pad on the second side of the substrate. Each of the TSVs can be in contact with an array of the dummy structures. The coupling between the TSVs and the active transistors via the dummy structures can provide shorter current paths for the active transistors on the first side of the substrate and electrical components in the chip bonded to the second side of the substrate and can improve the performance of the semiconductor device by reducing the RC delay.

In some embodiments, a device can include first, second, and third chips, with the second chip bonded to the first chip, and the third chip bonded to the second trip. The first chip can include photoelectric sensors on a first side of the first chip and a first interconnect structure on a second side of the first chip and electrically coupled to the photoelectric sensors. The second chip can include a second interconnect structure and a device layer on a first side of the second chip. The second interconnect structure can be electrically coupled to the first interconnect structure. The device layer can include a plurality of active transistors coupled to the second interconnect structure and a plurality of dummy transistors electrically coupled to the plurality of active transistors. The second chip can further include a TSV electrically coupled to the plurality of dummy transistors from a second side of the second chip. The third chip can include an image processor a third interconnect structure coupling the image processor and the TSV.

In some embodiments, a device can include a plurality of active transistors on a first side of a substrate, a plurality of dummy transistors on the first side of the substrate and electrically coupled to the plurality of active transistors, and an interconnect structure on the plurality of active transistors The device can further include a conductive pad on a second side of the substrate and a TSV electrically coupled to the plurality of dummy transistors and the conductive pad. The device can further include a first chip bonded with the substrate on the first side of the substrate and having an image sensor electrically coupled to the interconnect structure. The device can further include a second chip bonded with the substrate on the second side of the substrate and having an image processor electrically coupled to the TSV.

In some embodiments, a method can include forming a plurality of active transistors and a plurality of dummy transistors on a first side of a substrate, forming buried contacts on the substrate to couple the plurality of active transistors and the plurality of dummy transistors, and forming a first interconnect structure on the plurality of active transistors. The method can further include forming an opening from a second side of the substrate to expose the plurality of dummy transistors and depositing a conductive material in the opening to form a TSV. The method can further include providing a first chip including a second interconnect structure and bonding the substrate with the first chip by forming a first contact between the first and second interconnect structures. The method can further include providing a second chip that includes a third interconnect structure and bonding the substrate with the second chip by forming a second contact between the TSV and third interconnect structure.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a first chip, wherein the first chip comprises:
photoelectric sensors on a first side of the first chip; and
a first interconnect structure on a second side of the first chip and electrically coupled to the photoelectric sensors;
a second chip bonded with the first chip, wherein the second chip comprises:
a second interconnect structure on a first side of the second chip and electrically coupled to the first interconnect structure;
a plurality of active transistors coupled to the second interconnect structure;
a plurality of dummy transistors electrically coupled to the plurality of active transistors; and
a through silicon via (TSV) electrically coupled to the plurality of dummy transistors from a second side of the second chip; and
a third chip bonded with the second chip, wherein the third chip comprises:
an image processor; and
a third interconnect structure coupling the image processor and the TSV.

2. The device of claim 1, wherein the TSV is in contact with gate structures of the plurality of dummy transistors.

3. The device of claim 1, wherein the TSV is in contact with source/drain regions of the plurality of dummy transistors.

4. The device of claim 1, wherein the TSV is in contact with a bonding pad on the second side of the second chip, wherein the bonding pad is bonded with another bonding pad on the third chip.

5. The device of claim 1, wherein an aspect ratio of the TSV is between about 10 and about 1000.

6. The device of claim 1, wherein a width of the TSV is between about 1 μm and about 300 μm.

7. The device of claim 1, wherein a cross section of the TSV is circular.

8. A device, comprising:
a plurality of active transistors on a first side of a substrate;
a plurality of dummy transistors on the first side of the substrate and electrically coupled to the plurality of active transistors;
an interconnect structure on the plurality of active transistors;
a conductive pad on a second side of the substrate;
a through-silicon via (TSV) electrically coupled to the plurality of dummy transistors and the conductive pad;
a first chip bonded with the substrate on the first side of the substrate, wherein an electronic device on the first chip is electrically coupled to the interconnect structure; and
a second chip bonded with the substrate on the second side of the substrate, wherein a processing device on the second chip is electrically coupled to the TSV.

9. The device of claim 8, wherein the TSV is in contact with source/drain regions of the plurality of dummy transistors, wherein a ratio of a width of the TSV to a width of each of the source/drain regions is between about 10 and about 10,000.

10. The device of claim 9, wherein a pitch of the source/drain regions is greater than 50 nm.

11. The device of claim 8, wherein the TSV is in contact with gate structures of the plurality of dummy transistors, and wherein a ratio of a width of the TSV to a width of each of the gate structures is between about 10 and about 15,000.

12. The device of claim 11, wherein a pitch of the gate structures is greater than about 50 nm.

13. The device of claim 8, wherein the TSV is in contact with gate structures and source/drain regions of the plurality of dummy transistors.

14. The device of claim 8, wherein the TSV comprises tungsten, aluminum, copper, or ruthenium.

15. A method, comprising:
forming a plurality of active transistors and a plurality of dummy transistors on a first side of a substrate;
forming buried contacts on the substrate to couple the plurality of active transistors and the plurality of dummy transistors;
forming a first interconnect structure on the plurality of active transistors;
forming an opening from a second side of the substrate to expose the plurality of dummy transistors;
depositing a conductive material in the opening to form a through silicon via (TSV);
providing a first chip comprising a second interconnect structure;
bonding the substrate with the first chip by forming a first contact between the first and second interconnect structures;
providing a second chip comprising a third interconnect structure; and
bonding the substrate with the second chip by forming a second contact between the TSV and the third interconnect structure.

16. The method of claim 15, wherein forming the plurality of dummy transistors comprises forming an array of gate structures of the plurality of dummy transistors.

17. The method of claim 15, wherein forming the plurality of dummy transistors comprises forming an array of source/drain regions of the plurality of dummy transistors.

18. The method of claim 15, further comprising forming a bonding pad on the second side of the substrate and in contact with the TSV.

19. The method of claim 18, wherein bonding the substrate with the second chip comprises forming an electrical connection between the bonding pad and another bonding pad on the second chip.

20. The method of claim 15, wherein bonding the substrate with the first chip comprises performing a hybrid bonding operation.
